(19) United States
(12) Patent Application Publication
(10) Pub. No.: US 2008/0150435 A1
(43) Pub. Date: Jun. 26, 2008

(54) DISPLAY DEVICES WITH ORGANIC LIGHT EMITTING LAYERS

(76) Inventors: Seung-kyu Park, Gyeonggi-do (KR); Tae-youn Kim, Ulsan (KR)

Correspondence Address: MACPHERSON KWOK CHEN & HEID LLP, 2033 GATEWAY PLACE, SUITE 400, SAN JOSE, CA, 95110, US

(21) Appl. No.: 11/939,288

(22) Filed: Nov. 13, 2007

(30) Foreign Application Priority Data
Dec. 26, 2006 (KR) 10-2006-0134185

(51) Int. Cl. H01L 27/32; H01L 21/84

(52) U.S. Cl. 315/169.3; 438/23; 257/E21.7; 257/E27.111

(57) ABSTRACT

A display device comprises: an insulating substrate; a first electrode formed over the insulating substrate and physically contacting the insulating substrate; an organic layer which is formed over the first electrode and includes an organic light emitting layer; and a second electrode which is formed over the organic layer.

### CROSS-REFERENCE TO RELATED APPLICATIONS

This application claims priority from Korean Patent Application No. 2006-0134185, filed on Dec. 26, 2006 in the Korean Intellectual Property Office, the disclosure of which is incorporated herein by reference.

### BACKGROUND OF INVENTION

1. Field of Invention

The present invention relates to display devices having organic light emitting layers (such as organic light emitting diode displays, or OLEDs). The invention can be used with bottom-emission OLEDs in which the organic light emitting layer emits light passing through an insulating substrate on the way to the viewer.

2. Description of the Related Art

In the field of flat panel displays, organic light emitting diode displays (OLED) have recently been in the limelight owing to their low voltage requirements, small weight, thin shape, a wide viewing angle, fast response, and other advantages.

The organic light emitting diode displays can be divided into bottom emission type and top emission type according to the direction of light emitted by the light emitting layer. In the bottom emission type, the light generated in the light emitting layer passes through an insulating substrate on the way to the viewer. The display includes an insulating layer and/or an organic layer between the light emitting layer and the insulating substrate, and some of the light energy is lost in the insulating layer and the organic layer. Further, the insulating layer and the organic layer cause color distortion.

### SUMMARY

This section summarizes some features of the invention. Other features are described in subsequent sections. The invention is defined by the appended claims.

Some embodiments of the present invention provide a display device with an improved light efficiency.

Some embodiments provide a display device comprising: an insulating substrate; a first electrode formed over the insulating substrate and physically contacting the insulating substrate; an organic layer which is formed over the first electrode and includes an organic light emitting layer; and a second electrode which is formed over the organic layer.

In some embodiments, the display device further comprises: a thin film transistor which is formed over the insulating substrate; and an insulating layer which is formed over the thin film transistor and comprises a contact hole to expose the thin film transistor, the first electrode being connected to the thin film transistor through the contact hole.

In some embodiments, the first electrode comprises a first portion all of which is in physical contact with the insulating substrate and a second portion which does not physically contact the insulating substrate; wherein the display device further comprises a wall layer formed over the insulating layer, and an aperture region in the wall layer, wherein the aperture region is aligned with the first portion substantially not to laterally extend beyond the first portion.

In some embodiments, the first electrode comprises a first portion all of which is in physical contact with the insulating substrate and a second portion which does not physically contact the insulating substrate; wherein the display device further comprises a wall layer which is formed on the insulating layer and comprises an aperture region to at least partially expose the first portion, where the aperture region overlies all of the first portion and at least part of a horizontal top surface of the second portion.

In some embodiments, the insulating layer and the wall layer are in physical contact with each other.

In some embodiments, the second electrode comprises a reflective metal layer.

In some embodiments, at least a part of the organic layer is in physical contact with the second portion.

Some embodiments provide a method of manufacturing a display device, the method comprising: forming a thin film transistor over an insulating substrate; forming an insulating layer over the thin film transistor; patterning the insulating layer to form: (i) an exposure region exposing the insulating substrate, and (ii) a contact hole exposing the thin film transistor; forming a first electrode which is electrically connected to the thin film transistor via the contact hole and comprises a first portion positioned in the exposure region and a second portion surrounding the first portion; forming a photoresist layer over the first electrode; patterning the photoresist layer to form a wall layer which has an aperture region to at least partially expose the first portion; forming an organic layer comprising an organic light emitting layer over the first electrode; and forming a second electrode over the organic layer.

In some embodiments, the wall layer is formed so that a boundary of the aperture region overlies the second portion.

In some embodiments, the patterning of the insulating layer comprises photolithographic patterning of the insulating layer using a first mask defining the exposure region and a second mask defining the contact hole; and wherein the patterning of the photoresist layer comprises exposing the photoresist layer using the first mask.

In some embodiments, the second electrode comprises a reflective metal layer.

In some embodiments, the insulating layer and the wall layer are in physical contact with each other.

In some embodiments, at least a part of the organic layer is in physical contact with the second portion.

Some embodiments provide a method of manufacturing a display device, the method comprising: forming a gate electrode over an insulating substrate; forming a first insulating layer over the gate electrode; forming a polysilicon layer over the first insulating layer in a predefined position relative to the gate electrode; forming a source electrode and a drain electrode each of which at least partially overlies the polysilicon layer, and which are spaced apart from each other; forming a second insulating layer over the source electrode and the drain electrode; patterning the first and second insulating layers to form an exposure region to expose the insulating substrate and also to form a contact hole to expose the thin film transistor; forming a first electrode which is electrically connected to the thin film transistor via the contact hole and comprises a first portion positioned in the exposure region and a second portion surrounding the first portion; forming a photoresist layer on the first electrode; patterning the photoresist layer to form a wall which has an aperture region to at least partially expose the first portion; forming an organic layer comprising an organic light emitting layer over the first electrode; and forming a second electrode over the organic layer.

In some embodiments, the patterning of the first and second insulating layers comprises: forming the exposure region by photolithography using a first mask; and forming the contact hole by photolithography using a second mask; wherein the patterning of the photoresist layer comprises exposing the photoresist layer using the first mask.

Some embodiments provide a method of manufacturing a display device, the method comprising: forming a thin film transistor over an insulating substrate; forming an insulating layer over the thin film transistor; patterning the insulating layer to form openings through the insulating layer, one of the openings being an exposure region, another one of the openings being a contact hole exposing the thin film transistor; forming a first electrode which is electrically connected to the thin film transistor via the contact hole and comprises a first portion positioned in the exposure region and a second portion surrounding the first portion; forming a wall layer and patterning the wall layer to form an aperture region to at least partially expose the first portion; forming an organic layer comprising an organic light emitting layer over the first electrode; and forming a second electrode over the organic layer; wherein the patterning of the insulating layer comprises photolithographic patterning of the insulating layer using a first mask defining the exposure region and a second mask defining the contact hole; and wherein the patterning of the wall layer comprises exposing a photoresist layer using the first mask. Other aspects of the invention are described below. The invention is defined by the appended claims.

### BRIEF DESCRIPTION OF THE DRAWINGS

The above and/or other aspects of the present invention will become apparent and more readily appreciated from the following description of exemplary embodiments, taken in conjunction with the accompanying drawings, in which:

FIG. 1 is a circuit diagram of a display device according to a first embodiment of the present invention;

FIG. 2 is a plan view of the display device according to the first embodiment of the present invention;

FIG. 3 shows a vertical cross section of the display device along line III-III of FIG. 2;

FIGS. 4A through 4H show vertical cross sections of the display device according to the first embodiment of the present invention in the process of fabrication;

FIG. 5 shows a vertical cross section of the display device according to a second embodiment of the present invention; and

FIGS. 6A through 6F show vertical cross sections of the display device according to the second embodiment of the present invention in the process of fabrication.

### DETAILED DESCRIPTION OF EXEMPLARY EMBODIMENTS

Some embodiments of the present invention will now be described in detail with reference to the accompanying drawings, wherein like reference numerals refer to like elements throughout.

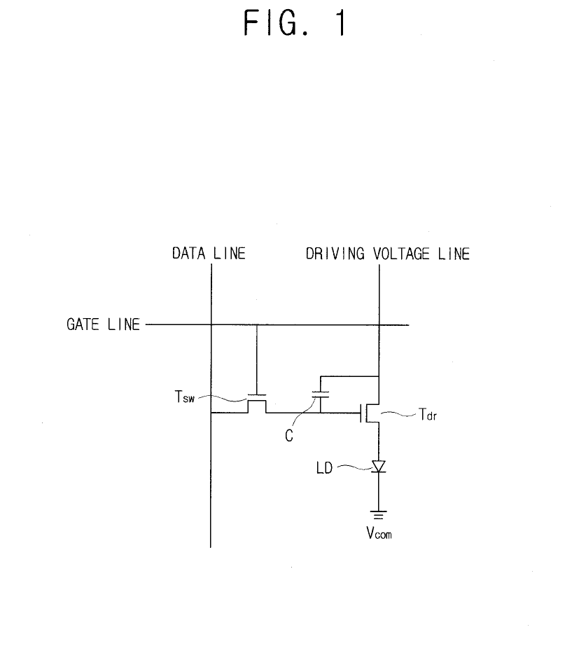

FIG. 1 is a circuit diagram of a display according to a first embodiment of the present invention.

Each pixel of the display is associated with a plurality of signal lines including a gate line transferring a scanning signal, a data line transferring a data signal, and a driving voltage line transferring a driving voltage. The data line and the driving voltage line are parallel and adjacent to each other, and are perpendicular to the gate line.

Each pixel includes an organic light emitting diode LD, a switching thin film transistor Tsw, a driving thin film transistor Tdr, and a capacitor C.

The driving thin film transistor Tdr has a control terminal, an input terminal, and an output terminal. The control terminal is connected to the switching thin film transistor Tsw. The input terminal is connected to the driving voltage line. The output terminal is connected to the organic light emitting diode LD.

The organic light emitting diode LD has an anode connected to the output terminal of the driving thin film transistor Tdr and a cathode receiving a common voltage Vcom. The light power emitted by the organic light emitting diode LD is controlled by the output voltage of the driving thin film transistor Tdr to obtain a desired image. The magnitude of the current of the driving thin film transistor Tdr depends on the voltage between the control terminal and the output terminal.

The switching thin film transistor Tsw also has a control terminal, an input terminal, and an output terminal. The control terminal is connected to the gate line, the input terminal is connected to the data line, and the output terminal is connected to the control terminal of the driving thin film transistor Tdr. The switching thin film transistor Tsw transfers the data signal provided on the data line to the driving thin film transistor Tdr synchronously with a scanning signal on the gate line.

The capacitor C is connected between the control terminal and the input terminal of the driving thin film transistor Tdr. The capacitor C stores the charge supplied by the data signal provided to the control terminal of the driving thin film transistor Tdr.

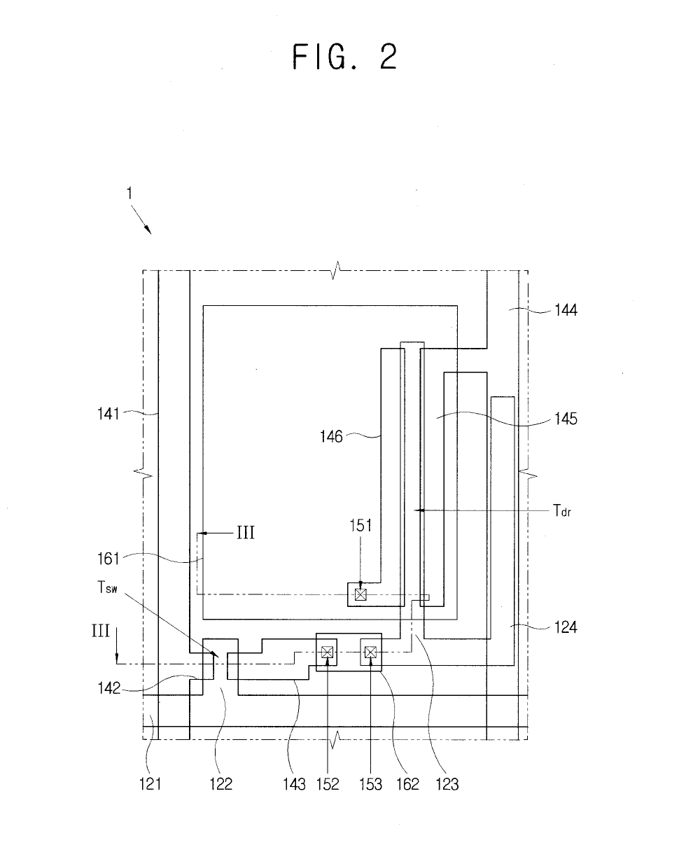

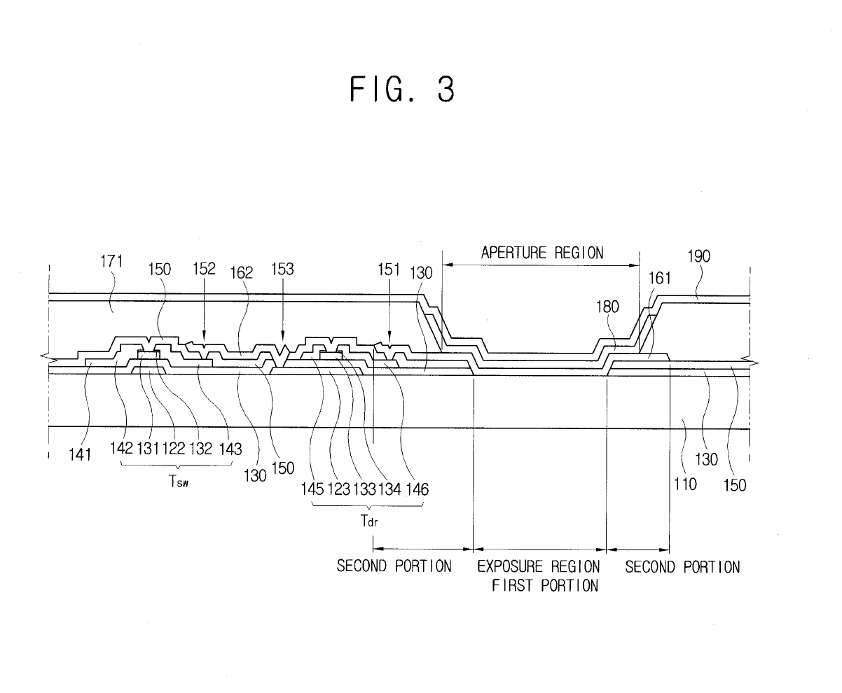

A display device according to the first embodiment of the present invention will now be described in detail with reference to FIGS. 2 and 3.

In this device, gate wires 121, 122, 123, 124 are formed on a transparent insulating substrate 110. Gate wires 121 are gate lines arranged in parallel at regular intervals. Switching gate electrodes 122 are gate electrodes of the switching transistors Tsw. Driving gate electrodes 123 are gate electrodes of the driving transistors Tdr. Each capacitor feature 124 extends below the corresponding driving voltage line 144 and provides one electrode to a corresponding capacitor C (FIG. 1).

In this embodiment, each gate line 121 is formed integrally, in the same layer, with the corresponding switching gate electrodes 122. Also, in each pixel, the driving gate electrode 123 and the capacitor feature 124 are formed integrally in the same layer.

A first insulating layer 130 is formed over the gate wires. The first insulating layer 130 includes an inorganic material, silicon nitride for example. Part of the first insulating layer 130 physically contacting the insulating substrate 110 is removed to form an “exposure region” in which the insulating substrate 110 is exposed. A second insulating layer 150, described below, will also be removed in the exposure region.

Semiconductor features 131 (“switching semiconductor features”) are formed on the gate insulating layer 130 above the corresponding switching gate electrodes 122. Also, semiconductor features 133 (“driving semiconductor features”) are formed on the gate insulating layer 130 above the corresponding driving gate electrodes 123. The semiconductor features 131 and 133 can be made of amorphous silicon, nanocrystalline silicon, polysilicon, or other suitable materials.

Ohmic contact features 132 and 134 are located on the semiconductor features 131 and 133. Two “switching” ohmic contact features 132 are formed on the corresponding switching semiconductor feature 131 at different sides of the corresponding gate electrode 122. Two “driving” ohmic contact features 134 are formed on the corresponding driving semiconductor feature 133 at different sides of the corresponding gate electrode 123.

The ohmic contact features 132 and 134 include n+ silicon or some other suitable material. If the semiconductor features 131 and 133 include polysilicon, the ohmic contact features 132 and 134 also include polysilicon.

Data wires are formed over the ohmic contact features 132 and 134 and the gate insulating layer 130. The data wires include a plurality of data lines 141 parallel to each other and perpendicular to the gate lines 121. The data wires also include source electrodes 142 (“switching source electrodes”) and drain electrodes 143 (“switching drain electrodes”) of the switching thin film transistors Tsw. The data wires include driving voltage lines 144 which carry driving voltages. The data wires also include source electrodes 145 (“driving source electrodes”) and drain electrodes 146 (“driving drain electrodes”) of the driving thin film transistors Tdr.

In this embodiment, each data line 141 is formed integrally, in the same layer, with the corresponding switching source electrodes 142. Also, each driving voltage line 144 is formed integrally, in the same layer, with the corresponding driving source electrodes 145.

The second insulating layer 150 is formed over the data wires and the semiconductor features 131 and 133. The second insulating layer 150 may include silicon nitride, silicon oxide, or some other suitable material.

Contact holes 151, 152, 153 are formed in the second insulating layer 150. Each contact hole 151 exposes a corresponding driving drain electrode 146. Each contact hole 152 exposes a corresponding switching drain electrode 143. In each contact hole 153, the first insulating layer 130 is removed to expose a corresponding driving gate electrode 123.

As described above, the second insulating layer 150 and the first insulating layer 130 are removed in the exposure regions to expose the insulating substrate 110.

A transparent conductive layer is formed over the second insulating layer 150 and the insulating substrate 110 in the exposure regions to provide pixel electrodes 161 and bridge electrodes 162. The transparent conductive layer can be indium tin oxide (ITO) or indium zinc oxide (IZO).

Each pixel electrode 161 is electrically connected to the corresponding driving drain electrode 146 via the corresponding contact hole 151. Each pixel electrode 161 includes a first portion formed in the corresponding exposure region and a second portion surrounding the first portion. The first portion physically contacts the insulating substrate 110. The second portion does not physically contact the insulating substrate 110 and overlaps the insulating layers 130 and 150. The second portion is connected to the driving drain electrode 146.

The bridge electrode 162 electrically connects the switching drain electrode 143 to the driving gate electrode 123 via the contact holes 152 and 153.

A layer 171 is formed over the second insulating layer 150 to provide a wall separating the pixel electrodes 161 from each other. Parts of wall layer 171 are removed to form an aperture region for each pixel. The wall 171 includes a heat resistant and solvent resistant photoresist such as acryl resin, polyimide resin, and/or other suitable materials.

In this embodiment, the insulating substrate 110 has a highly smooth upper surface. Therefore, there is no need to provide a planarization layer between the insulating substrate 110 and the first portion of the pixel electrode 161. The wall 171 physically contacts the second insulating layer 150 because there is no planarization layer in between.

Each aperture region in the wall 171 is somewhat lager than the exposure region in the same pixel. The aperture region's boundary is located over the second portion of the pixel electrode 161. In fact, the second portion has a part with a horizontal top surface over the insulating layers 130, 150 and has a part with a sloping top surface adjacent to the first portion, and the aperture region's boundary is located over the horizontal top surface of the second portion.

An organic layer 180 is formed over the pixel electrodes 161 and the wall 171. The organic layer 180 includes an organic light emitting layer, and may further include an electron injection layer, an electron transport layer, a hole injection layer, a hole transport layer, and/or other suitable layers.

The hole injection layer and the hole transport layer include an amine derivative having a strong fluorescent property such as a triphenyldiamine derivative, a styryl amine derivative, and/or an amine derivative having an aromatic condensed ring.

The electron transport layer may includes a quinoline derivative, for example, aluminum tris (8-hydroxyquinoline) (Alq3). Further, the electron transport layer may include a phenyl anthracene derivative, and a tetraarylethen derivative. The electron injection layer may include barium or calcium.

The organic light emitting layer in each pixel may emit light of a predefined color, e.g. red, green or blue, with adjacent pixels having light emitting layers emitting light of respective different colors.

The organic layer 180 may be formed by thermal evaporation or inkjet deposition.

A common electrode 190 is formed over the organic layer 180 and the wall 171. The common electrode 190 includes a reflective metal layer.

The display operates as follows. Holes from the pixel electrode 161 and electrons from the common electrode 190 are combined into excitons in the organic layer 180, and the excitons emit light while being inactivated. The light emitted from the organic layer 180 is reflected from the common electrode 190 toward the pixel electrode 161. In this embodiment, the pixel electrode 161 is substantially transparent to allow the light to pass through the pixel electrode 161 and the insulating substrate 110 on the way to the viewer, outside of the display.

Most of the light traveling outside passes only through the pixel electrode 161 and the insulating substrate 110, without having to pass through the insulating layers 130, 150. In particular, the light passing through the first portion of the pixel electrode 161 (the portion positioned in the exposure region) exits the display without having to pass through the insulating layers 130 and 150. Therefore, the light energy loss attributed to the insulating layers 130 and 150 is reduced, so that light efficiency is improved. Also, the color is not distorted by the insulating layers 130 and 150.

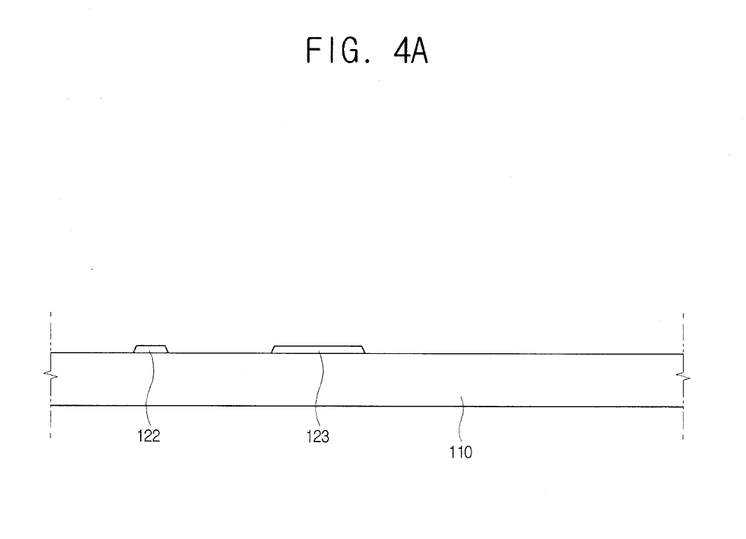

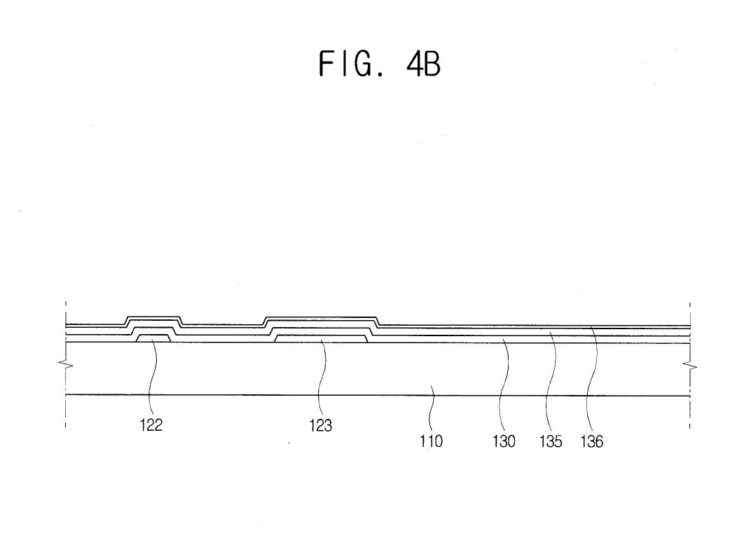

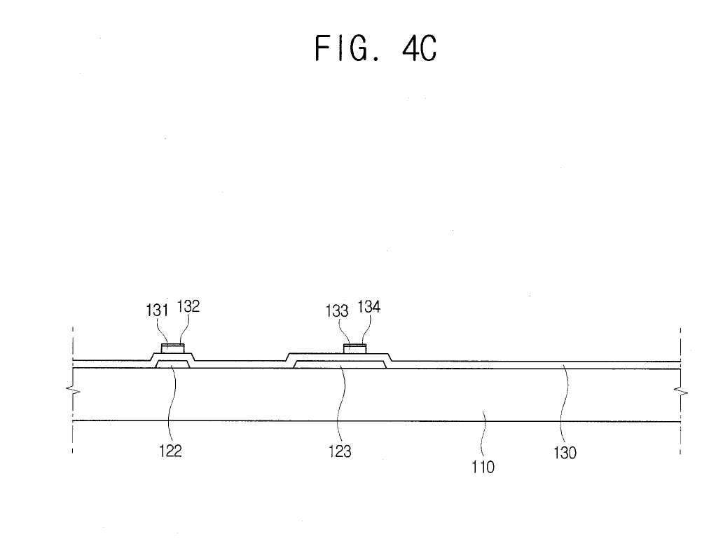

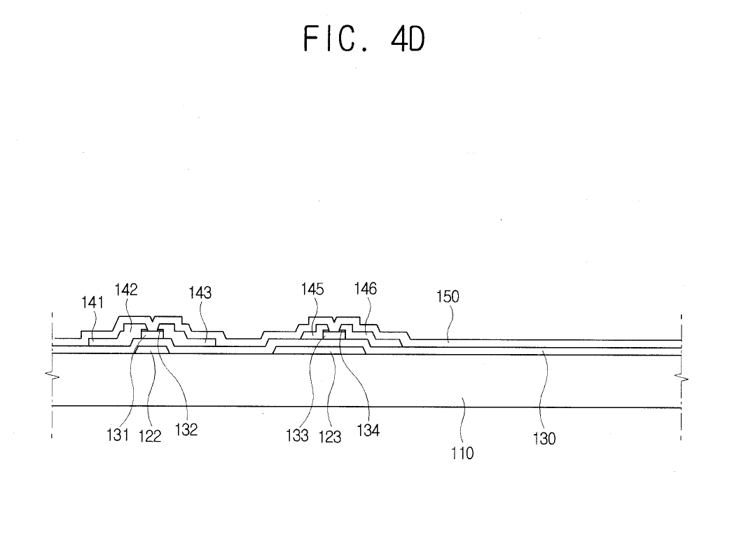

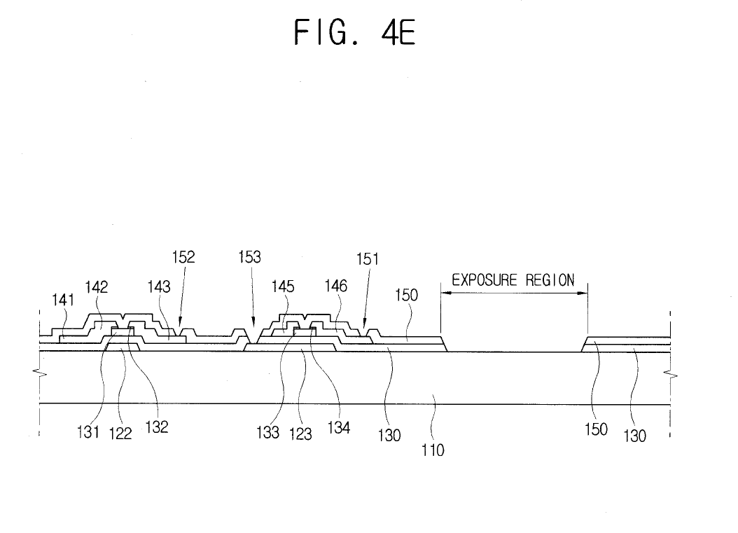

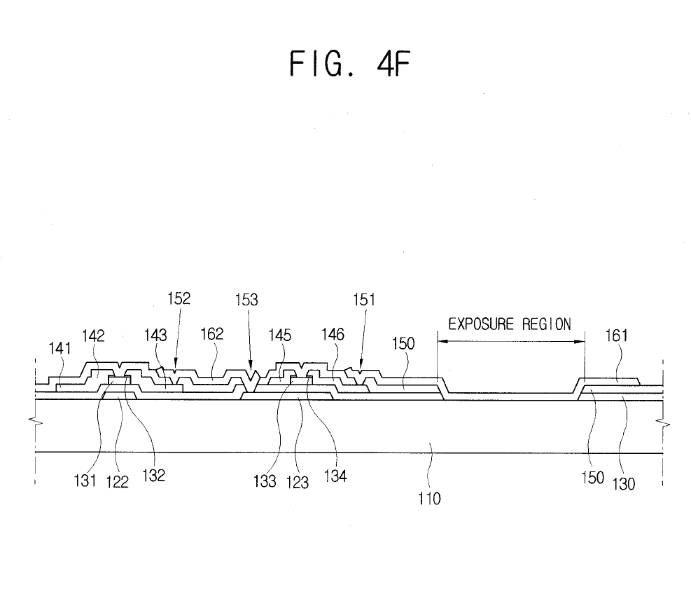

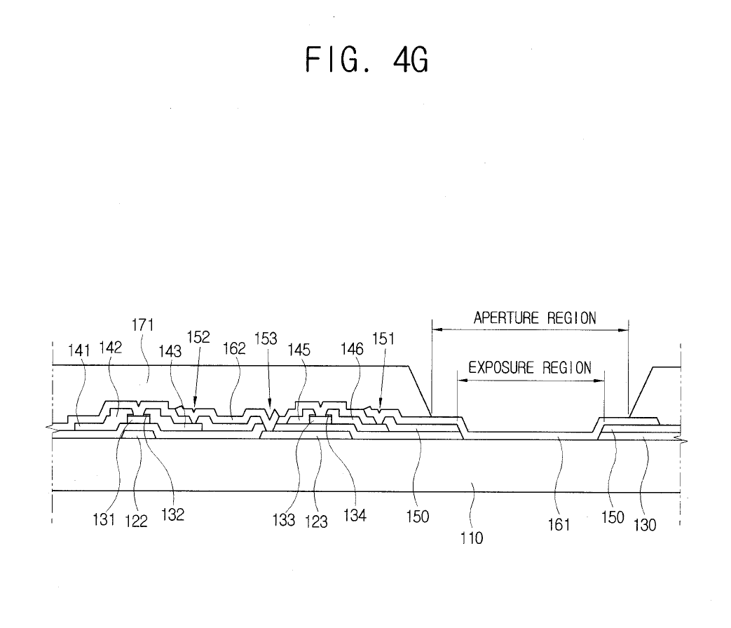

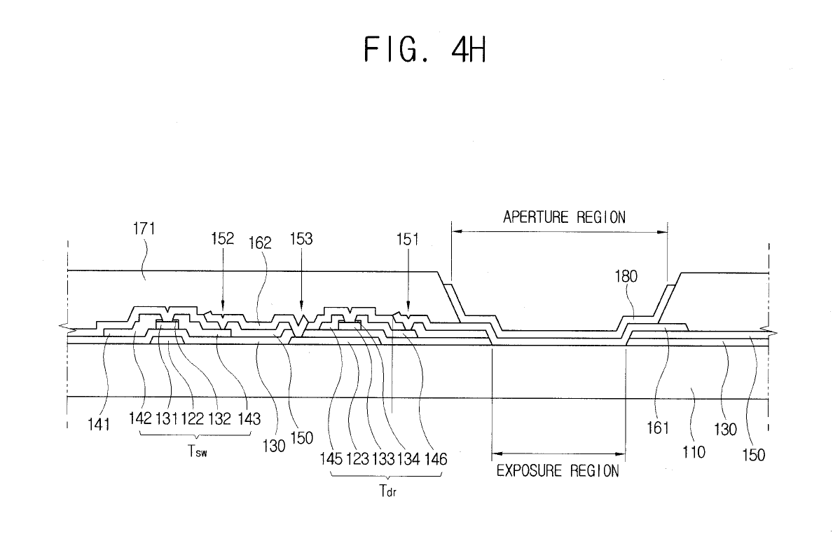

Manufacturing of a display device according to the first embodiment of the present invention will now be described with reference to FIGS. 4A through 4H. For the sake of example, it will be assumed that the semiconductor features 131 and 133 and the ohmic contact features 132 and 134 are made of polysilicon, and the organic layer 180 is formed by dry deposition (e.g. vapor deposition).

First, as shown in FIG. 4A, a metal layer is formed on the insulating substrate 110 and patterned to form the gate electrodes 122 and 123.

Then, as shown in FIG. 4B, the first insulating layer 130, an amorphous silicon layer 135 and an n+ amorphous silicon layer 136 are formed.

Then the amorphous silicon layer 135 and the n+ amorphous silicon layer 136 are crystallized. The crystallization may involve solid phase crystallization, laser crystallization, and/or a rapid thermal process.

Solid phase crystallization involves an anneal performed at low temperatures of at most 600° C. for a relatively long time to get large grain polysilicon. Laser crystallization involves an anneal performed using a laser (for example, excimer laser), followed by solidification, etc., to obtain polysilicon. The rapid thermal process uses light energy to rapidly heat the amorphous silicon surface from a low temperature to a high temperature.

After the amorphous silicon layer 135 and the n+ amorphous silicon layer 136 have been crystallized, they are patterned to form the semiconductor features 131 and 133 and the ohmic contact features 132 and 134 (FIG. 4C). The features 131-134 are made of polysilicon in this example. As described above, there is a pair of ohmic contact features 132 on each feature 131, but the ohmic contact features 132 within each pair have not yet been separated from each other in layer 136 because the layers 135, 136 have been patterned using the same mask (not shown). Similarly, in each pair of ohmic contact features 134 on each feature 133, the features 134 have not yet been separated from each other in layer 136.

Then (FIG. 4D) the switching source electrodes 142, the switching drain electrodes 143, the driving source electrodes 145, and the driving drain electrodes 146 are formed by depositing and patterning a metal layer. Then the exposed portions of silicon layer 136 are etched selectively to this metal layer to separate the ohmic contacts 132, 134 within each ohmic contact pair from each other, i.e. to remove the portions of layer 136 between the ohmic contacts. This etch may attack the semiconductor layer 136 between the semiconductor features 131 and 133 to thin down the channel regions of the switching transistors Tsw and the driving transistors Tdr. This etch completes the fabrication of the switching transistors Tsw and the driving transistors Tdr.

Then the second insulating layer 150 is formed.

As shown in FIG. 4E, the first insulating layer 130 and the second insulating layer 150 are then patterned photolithographically to simultaneously form the exposure regions and the contact holes 151, 152, and 153.

As shown in FIG. 4F, the transparent conductive layer such as ITO or IZO is then deposited and photolithographically patterned to form the pixel electrodes 161 and the bridge electrodes 162. The first portion of each pixel electrode 161 is positioned in the corresponding exposure region in physical contact with the insulating substrate 110, and the rest of the pixel electrode 161 is positioned on the second insulating layer 150.

In each pixel, the bridge electrode 162 connects the switching drain electrode with the driving gate electrode 123 via the contact holes 152 and 153.

Then the wall 171 is formed. See FIG. 4G. The wall 171 can be a photoresist layer patterned by exposure to light and developing. The photoresist layer may be formed by slit coating, spin coating, or some other suitable process.

The aperture regions formed in the wall 171 expose the pixel electrodes 161 formed in the exposure regions. The aperture regions' boundaries are located on the second insulating layer 150.

Then the organic layer 180 (FIG. 4H) is then formed. The organic layer 180 includes a plurality of layers including an organic light emitting layer, and may be formed by dry deposition.

A suitable dry deposition technique is thermal evaporation. In thermal evaporation, the display structure is arranged with the pixel electrode 161 on the bottom. Then organic materials are evaporated onto the bottom surface of the display structure. The evaporation may be conducted using a shadow mask. If an open mask is used instead, the organic material is deposited over the wall 171. In some variations, part of the organic layer 180 may be deposited using an open mask, and the remainder of the organic layer 180 may be deposited using a shadow mask.

In other embodiments, the organic layer 180 is formed by a wet deposition method such as inkjet method. In this case, the organic layer 180 is mostly restricted to the aperture region.

Then the common electrode 190 is formed, thus completing the fabrication of the display device shown in FIGS. 2 and 3.

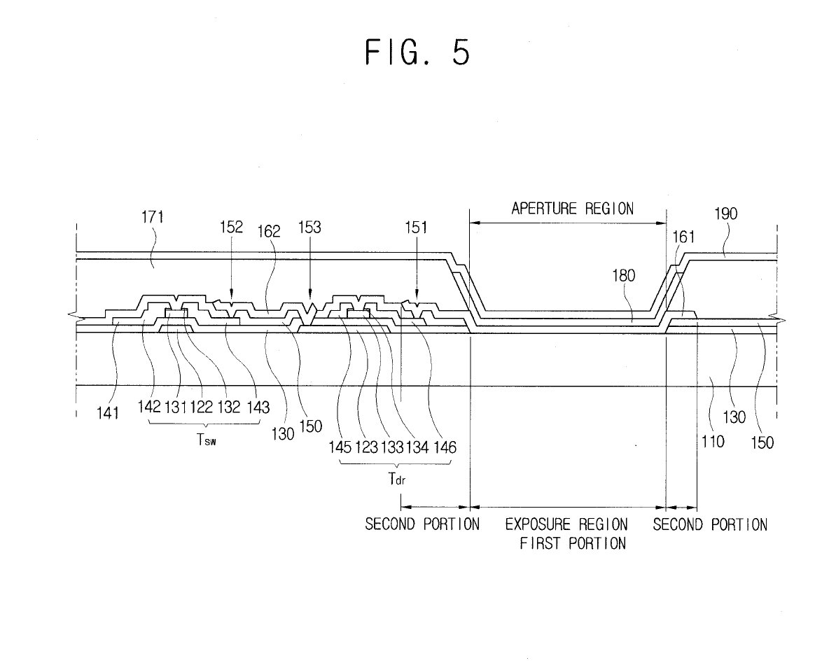

The display device according to the second embodiment of the present invention will now be described with reference to FIG. 5. Some elements of the second embodiment are identical or similar to those of the first embodiment, and repetitive description of such elements will be avoided as appropriate.

In the second embodiment, each aperture region in the wall 171 is aligned to substantially coincide with the corresponding exposure region. The aperture region substantially does not laterally extend beyond the exposure region. In the first embodiment, the aperture region can be larger than the exposure region, and can overlie all of the first portion of the pixel electrode 161 and at least some of the second portion, including at least some of the second portion's horizontal top surface.

The boundaries of the wall 171 are positioned on the horizontal top surface of the second portion. An inclined area is formed between the first portion and the second portion. When the boundaries of the wall 171 are positioned on the inclined area, the organic layer 180 may not be stably formed on the inclined area thus the pixel electrode 161 and the common electrode 190 can be short-circuited. To avoid such short-circuit, the boundaries of the wall 171 may be distanced from the inclined area. In the second embodiment, the boundaries of the wall 171 are formed near the inclined region to maximize the exposure region.

In the second embodiment, the boundaries of the wall 171 can be formed over the sloping part of the second portion of the pixel electrode 161. The sloping part is inclined in same direction as the sidewalls of the wall 171, to reduce the probability of a short circuit between the pixel electrode 161 and the common electrode 190.

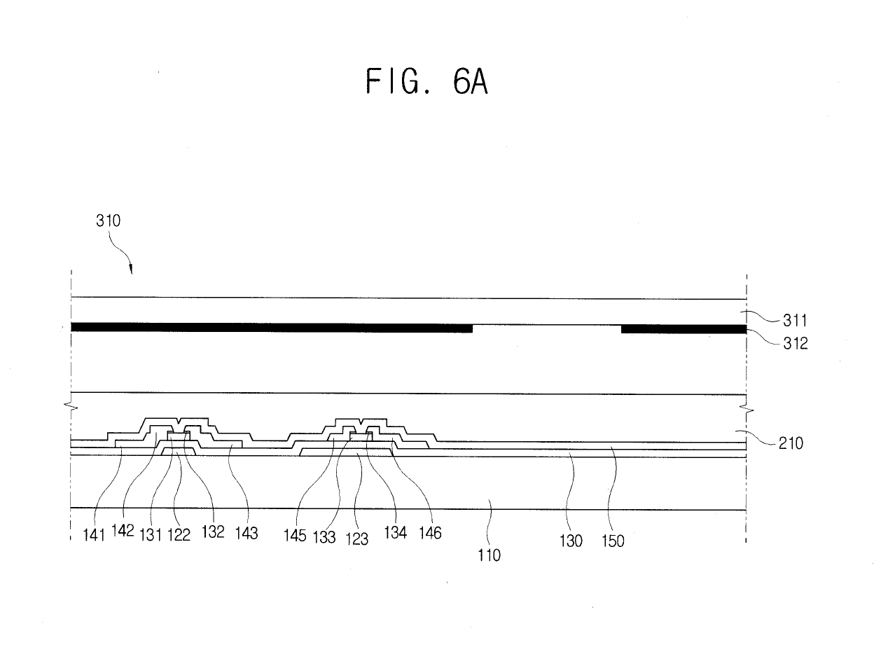

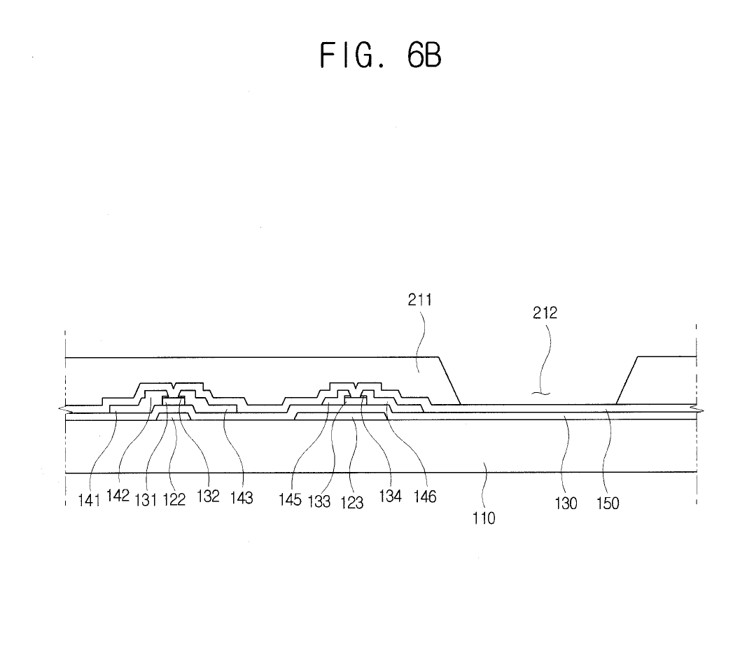

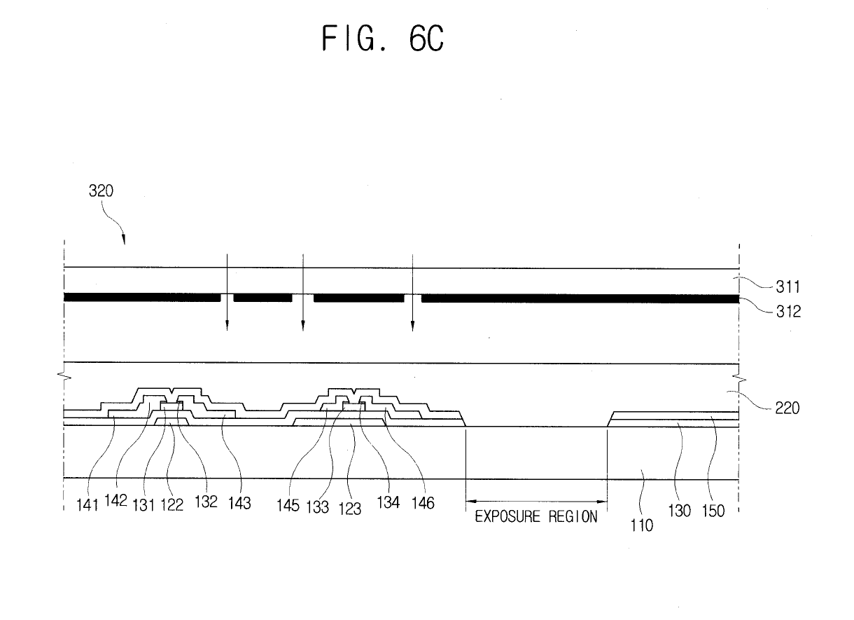

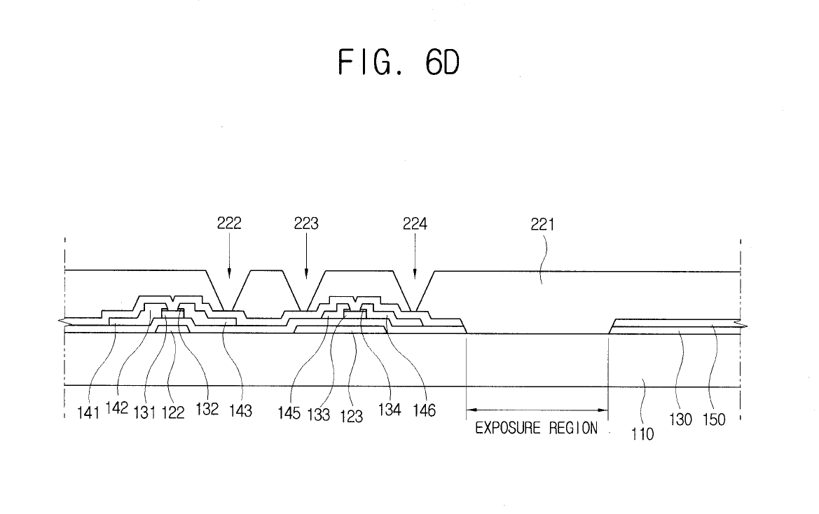

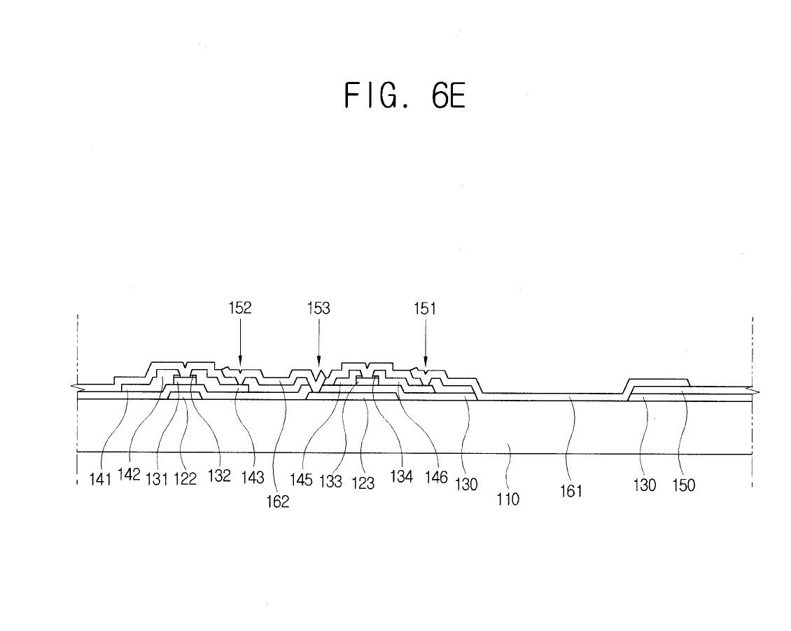

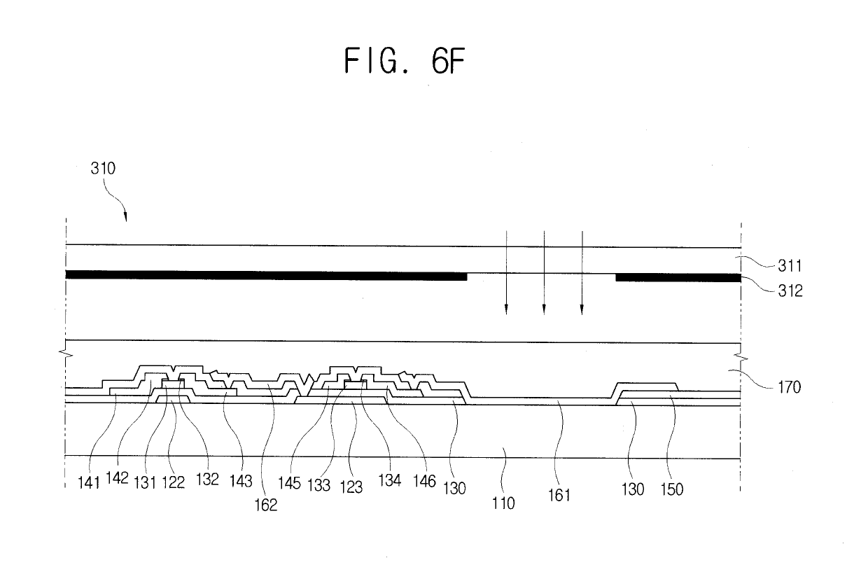

Manufacturing of a display device according to the second embodiment of the present invention will be described with reference to FIGS. 6A through 6E. FIGS. 6A through 6E illustrate the patterning of the insulating layers 130 and 150 and the fabrication of the wall 171.

Referring FIG. 6A, a first photoresist layer 210 is formed over the second insulating layer 150 and is exposed through a first mask 310. The first photoresist layer 210 may be formed by slit coating, spin coating, screen printing, or some other suitable technique.

The first mask 310 includes a mask substrate 311 made of quartz or some other material and a light blocking pattern 312 made of chrome or some other material. The light blocking pattern 312 is clear in the exposure regions, in which the insulating layers 130 and 150 are to be removed.

FIG. 6B shows a first photoresist layer pattern 211 formed by developing and baking the exposed first photoresist layer 210. Those portions of the first photoresist layer 210 which were exposed through the light blocking pattern 312 are decomposed to define the exposure regions 212 (i.e., layer 210 is positive photoresist, but negative resists can also be used). Each exposure region 212 corresponds to an aperture region.

The insulating layers 130 and 150 are etched using the first photoresist pattern 211 to expose the insulating substrate 110 in the exposure regions. Then a second photoresist layer 220 (FIG. 6C) is formed on top and exposed through a second mask 320. The second photoresist layer 220 may be formed by slit coating, spin coating, screen printing, or some other technique.

The second mask 320 includes a mask substrate 321 made of quartz or some other material and a light blocking pattern 322 made of chrome or some other material. The light blocking pattern 322 is clear in the regions in which the contact holes 151, 152 and 153 are to be formed.

FIG. 6D shows that a second photoresist layer pattern 221 formed by developing and baking the exposed second photoresist layer 220. Those portions of the second photoresist layer 220 which were not covered with the light blocking pattern 312 are decomposed to form contact hole regions 222, 223, 224. (Negative resists are used in other embodiments.) The insulating layers 130 and 150 exposed through the second photoresist pattern 221 are etched away, thereby forming the contact holes 151, 152 and 153.

Then the photoresist 220 is removed, and the pixel electrodes 161 and the bridge electrodes 162 are formed. See FIG. 6E.

Then a third photoresist layer 170 (FIG. 6F) is formed over the structure and exposed using the same first mask 310 as in FIG. 6A. The third photoresist layer 170 is exposed and developed to provide the wall 171 of FIG. 5.

Thus, the same first mask 310 is used to define both the first photoresist layer 210 for the exposure regions and the third photoresist layer 170 for the wall. Therefore, the aperture regions in the wall 171 are closely aligned with the exposure regions in the insulating layers 130 and 150.

As described above, some embodiments of the present invention provide a display device with an excellent light efficiency, and a method to manufacture the same.

Although a few exemplary embodiments of the present invention have been shown and described, it will be appreciated by those skilled in the art that changes may be made in these embodiments without departing from the principles of the invention, the scope of which is defined in the appended claims and their equivalents.

What is claimed is:

1. A display device comprising:
an insulating substrate;
a first electrode formed over the insulating substrate and physically contacting the insulating substrate;
an organic layer which is formed over the first electrode and includes an organic light emitting layer; and
a second electrode which is formed over the organic layer.

2. The display device according to claim 1, further comprising:
a thin film transistor which is formed over the insulating substrate; and
an insulating layer which is formed over the thin film transistor and comprises a contact hole to expose the thin film transistor,
the first electrode being connected to the thin film transistor through the contact hole.

3. The display device according to claim 2, wherein the first electrode comprises a first portion all of which is in physical contact with the insulating substrate and a second portion which does not physically contact the insulating substrate;
wherein the display device further comprises a wall layer formed over the insulating layer, and an aperture region in the wall layer, wherein the aperture region is aligned with the first portion substantially not to laterally extend beyond the first portion.

4. The display device according to claim 2, wherein the first electrode comprises a first portion all of which is in physical contact with the insulating substrate and a second portion which does not physically contact the insulating substrate;
wherein the display device further comprises a wall layer which is formed on the insulating layer and comprises an aperture region to at least partially expose the first portion,
where the aperture region overlies all of the first portion and at least part of a horizontal top surface of the second portion.

5. The display device according to claim 3, wherein the insulating layer and the wall layer are in physical contact with each other.

6. The display device according to claim 1, wherein the second electrode comprises a reflective metal layer.

7. The display device according to claim 1, wherein at least a part of the organic layer is in physical contact with the second portion.

8. A method of manufacturing a display device, the method comprising:
forming a thin film transistor over an insulating substrate;
forming an insulating layer over the thin film transistor;
patterning the insulating layer to form: (i) an exposure region exposing the insulating substrate, and (ii) a contact hole exposing the thin film transistor;
forming a first electrode which is electrically connected to the thin film transistor via the contact hole and comprises a first portion positioned in the exposure region and a second portion surrounding the first portion;
forming a photoresist layer over the first electrode;
patterning the photoresist layer to form a wall layer which has an aperture region to at least partially expose the first portion;
forming an organic layer comprising an organic light emitting layer over the first electrode; and
forming a second electrode over the organic layer.

9. The method according to claim 8, wherein the wall layer is formed so that a boundary of the aperture region overlies the second portion.

10. The method according to claim 8, wherein the patterning of the insulating layer comprises photolithographic patterning of the insulating layer using a first mask defining the exposure region and a second mask defining the contact hole; and
wherein the patterning of the photoresist layer comprises exposing the photoresist layer using the first mask.

11. The method according to claim 8, wherein the second electrode comprises a reflective metal layer.

12. The method according to claim 8, wherein the insulating layer and the wall layer are in physical contact with each other.

13. The method according to claim 8, wherein at least a part of the organic layer is in physical contact with the second portion.

14. A method of manufacturing a display device, the method comprising:
forming a gate electrode over an insulating substrate;
forming a first insulating layer over the gate electrode;
forming a polysilicon layer over the first insulating layer in a predefined position relative to the gate electrode;
forming a source electrode and a drain electrode each of which at least partially overlies the polysilicon layer, and which are spaced apart from each other;
forming a second insulating layer over the source electrode and the drain electrode;
patterning the first and second insulating layers to form an exposure region to expose the insulating substrate and also to form a contact hole to expose the thin film transistor;
forming a first electrode which is electrically connected to the thin film transistor via the contact hole and comprises a first portion positioned in the exposure region and a second portion surrounding the first portion;
forming a photoresist layer on the first electrode;
patterning the photoresist layer to form a wall which has an aperture region to at least partially expose the first portion;
forming an organic layer comprising an organic light emitting layer over the first electrode; and
forming a second electrode over the organic layer.

15. The method according to claim 14, wherein the patterning of the first and second insulating layers comprises:
forming the exposure region by photolithography using a first mask; and
forming the contact hole by photolithography using a second mask;
wherein the patterning of the photoresist layer comprises exposing the photoresist layer using the first mask.

16. A method of manufacturing a display device, the method comprising:
forming a thin film transistor over an insulating substrate;
forming an insulating layer over the thin film transistor;
patterning the insulating layer to form openings through the insulating layer, one of the openings being an exposure region, another one of the openings being a contact hole exposing the thin film transistor;
forming a first electrode which is electrically connected to the thin film transistor via the contact hole and comprises a first portion positioned in the exposure region and a second portion surrounding the first portion;
forming a wall layer and patterning the wall layer to form an aperture region to at least partially expose the first portion;
forming an organic layer comprising an organic light emitting layer over the first electrode; and
forming a second electrode over the organic layer;
wherein the patterning of the insulating layer comprises photolithographic patterning of the insulating layer using a first mask defining the exposure region and a second mask defining the contact hole; and
wherein the patterning of the wall layer comprises exposing a photoresist layer using the first mask.
